(19) United States
(12) Patent Application Publication
(10) Pub. No.: US 2023/0137608 A1
(43) Pub. Date: May 4, 2023

(54) Semiconductor Structures

(71) Applicant: UNIVERSITY OF LANCASTER, Lancaster Lancashire (GB)

(72) Inventors: Peter CARRINGTON, Lancaster (GB); Evangelia DELLI, Thessaloniki (GR)

(21) Appl. No.: 17/915,782

(22) PCT Filed: Jun. 15, 2021
(86) PCT No.: PCT/GB2021/051485

§ 371 Date: Sep. 29, 2022

(30) Foreign Application Priority Data
Jun. 15, 2020 (GB) 2009043.7

(51) Int. Cl. H01L 33/12; H01L 31/0304; H01L 31/0352; H01L 31/0392; H01L 31/18; H01L 33/00; H01L 33/04; H01L 33/30

(52) U.S. Cl. CPC H01L 33/12; H01L 31/03046; H01L 31/035236; H01L 31/0392; H01L 31/1844; H01L 31/1852; H01L 33/0066; H01L 33/04; H01L 33/30; H01S 5/343

(57) ABSTRACT

A semiconductor device comprises a substrate, one or more first III-semiconductor layers, and a plurality of superlattice structures between the substrate and the one or more first layers. The plurality of superlattice structures comprises an initial superlattice structure and one or more further superlattice structures between the initial superlattice structure and the one or more first layers. The plurality of superlattice structures is configured such that a strain-thickness product of semiconductor layer pairs in each superlattice structure of the one or more further superlattice structures is greater than or equal to a strain-thickness product of semiconductor layer pairs in superlattice structure(s) of the plurality of superlattice structures between that superlattice structure and the substrate. The plurality of superlattice structures is also configured such that a strain-thickness product of semiconductor layer pairs in at least one of the one or more further superlattice structures is greater than a strain-thickness product of semiconductor layer pairs in the initial superlattice structure.

The present disclosure relates to techniques for growing semiconductor layers on a lattice mismatched substrate, and to semiconductor structures and devices comprising one or more semiconductor layers and a lattice mismatched substrate.

Heteroepitaxial growth of thin films with high lattice mismatch to the underlying substrate leads to the formation of threading dislocations, which deteriorate the crystalline quality of the epilayer and hinders the performance of semiconductor devices.

For example, III-V compound semiconductors can be used to produce high performance optoelectronic devices operating in the spectral range from 1.3 to 15 pm which encompasses the technologically important mid-infrared (MIR) spectral range (of 2 to 5 μm). Traditionally, III-V compound semiconductors for MIR photonics have been grown on expensive and small sized wafers such as Gallium Antimonide (GaSb) and Indium Arsenide (InAs), resulting in a high fabrication cost. Direct integration of III-V semiconductors onto group IV semiconductor wafers, such as silicon (Si), is an attractive alternative to enable cost effective manufacturing.

However, the fundamental material dissimilarities, such as the large lattice mismatch (˜12% for GaSb grown on Si), the polar-nonpolar character of the interface (e.g. III-V/Si) and differences in the thermal expansion coefficient, can lead to the formation of threading dislocations (TDs) and antiphase domains (APDs) which degrade device performance, and makes the direct epitaxial growth of high quality semiconductors layers on a lattice mismatched substrate challenging.

The Applicant believes that there remains scope for improvements to semiconductor structures and devices.

A first aspect of the invention provides a semiconductor structure comprising:

a substrate;

one or more first semiconductor layers; and

a plurality of superlattice structures between the substrate and the one or more first layers, wherein the plurality of superlattice structures comprises an initial superlattice structure and one or more further superlattice structures between the initial superlattice structure and the one or more first layers;

wherein the plurality of superlattice structures is configured such that a strain-thickness product of semiconductor layer pairs in each superlattice structure of the one or more further superlattice structures is greater than or equal to a strain-thickness product of semiconductor layer pairs in superlattice structure(s) of the plurality of superlattice structures between that superlattice structure and the substrate; and

wherein the plurality of superlattice structures is configured such that a strain-thickness product of semiconductor layer pairs in at least one of the one or more further superlattice structures is greater than a strain-thickness product of semiconductor layer pairs in the initial superlattice structure.

A second aspect of the invention provides a method of forming a semiconductor structure, the method comprising:

forming an initial set of semiconductor layers on a substrate; and

forming one or more first semiconductor layers on the initial set of semiconductor layers;

wherein forming the initial set of semiconductor layers comprises forming a plurality of superlattice structures comprising an initial superlattice structure and one or more further superlattice structures;

wherein forming the plurality of superlattice structures comprises forming the plurality of superlattice structures such that a strain-thickness product of semiconductor layer pairs in each superlattice structure of the one or more further superlattice structures is greater than or equal to a strain-thickness product of semiconductor layer pairs in superlattice structure(s) between that superlattice structure and the substrate; and

wherein forming the plurality of superlattice structures comprises forming the plurality of superlattice structures such that a strain-thickness product of semiconductor layer pairs in at least one of the one or more further superlattice structures is greater than a strain-thickness product of semiconductor layer pairs in the initial superlattice structure.

Various embodiments are directed to a semiconductor structure which may form part of a semiconductor device (and a method of forming a semiconductor structure) in which a plurality of superlattice structures (each comprising a plurality of repeats of a pair of semiconductor layers) are provided between one or more first semiconductor layers, such as one or more III-V compound semiconductor epilayers, and a lattice mismatched substrate, such as a group IV semiconductor substrate.

The plurality of superlattice structures comprises an initial superlattice structure, e.g. nearest to the substrate, and one or more further superlattice structures between the initial superlattice structure and the one or more first layers.

In various embodiments, the strain-thickness product of semiconductor layer pairs in each superlattice structure of the one or more further superlattice structures is greater than or equal to the strain-thickness product of semiconductor layer pairs in superlattice structure(s) of the plurality of superlattice structures between that superlattice structure and the substrate. In addition, the strain-thickness product of semiconductor layer pairs in at least one of the one or more further superlattice structures is greater than the strain-thickness product of semiconductor layer pairs in the initial superlattice structure.

In other words, the plurality of superlattice structures is configured such that the strain-thickness product of semiconductor layer pairs in the superlattice structure nearest to the one or more first layers is greater than the strain-thickness product of semiconductor layer pairs in the (initial) superlattice structure nearest to the substrate. The plurality of superlattice structures is also configured such that starting from the (initial) superlattice structure nearest to the substrate and going towards the superlattice structure nearest to the one or more first layer(s), the strain-thickness product of semiconductor layer pairs in each superlattice structure is greater than or equal to the strain-thickness product of semiconductor layer pairs in the preceding superlattice structure.

As will be described in more detail below, the Applicant has found that increasing the strain-thickness product of the semiconductor layer pairs of the superlattice structures in this manner has the effect of enhancing the filtering effect of the plurality of superlattice structures. The use of this structure accordingly allows high crystalline quality semiconductor layers to be formed. Indeed, the Applicants have shown that the use of this structure can provide defect densities for a Gallium Antimonide (GaSb) layer grown on a silicon substrate of the order of around 10⁶ cm⁻².

It will accordingly be appreciated that various embodiments provide an improved semiconductor structure, and an improved method of forming a semiconductor structure.

The substrate may comprise any suitable substrate (wafer). The substrate may be formed from any suitable semiconductor material such as a group IV semiconductor material or otherwise. The semiconductor material of the substrate will have a particular lattice constant. In various particular embodiments, the substrate is made from silicon (Si), Germanium (Ge), or Gallium Arsenide (GaAs). The use of a silicon substrate can significantly reduce the cost of fabricating the semiconductor structure. Furthermore, silicon is considered among the most prevalent material platform for developing fully integrated on-chip Si photonic circuits, which may comprise several passive components such as waveguides and/or active components such as lasers, detectors, and the like.

The one or more first semiconductor layers may comprise any suitable such layer(s). The one or more first layers may comprise one or more epilayers of the semiconductor structure. The one or more first layers may comprise plural layers of one or more semiconductor materials, but in various particular embodiments comprises one layer of a (single) semiconductor material.

The one or more first layers may be formed from any suitable semiconductor material such as one or more III-V compound semiconductor materials. The (each) semiconductor material of the one or more first layers may have a particular lattice constant.

In various particular embodiments, the lattice constant of the (each) semiconductor material of the one or more first layers is different to (is mismatched to) the lattice constant of the semiconductor material of the substrate. For example, the lattice constant of the (each) semiconductor material of the one or more first layers may be larger than the lattice constant of the semiconductor material of the substrate, for example a few percent larger, e.g. >5%.

In various particular embodiments, the semiconductor material of the one or more first layers comprises Gallium Antimonide (GaSb), Gallium Arsenide (GaAs), Gallium Phosphide (GaP), Gallium Nitride (GaN), Gallium Arsenide Antimonide (GaAsSb), Gallium Indium Antimonide (GaInSb), Gallium Arsenide Phosphide (GaAsP), Gallium Indium Arsenide Antimonide (GaInAsSb), Indium Arsenide (InAs), Indium Phosphide (InP), Indium Arsenide Antimonide (InAsSb), Aluminium Antimonide (AlSb), or Aluminium Indium Antimonide (AlInSb), and the like.

As described above, even though the one or more first semiconductor layers are grown on a mismatched substrate, the (upper layer of the) one or more first layers may have a particularly high crystalline quality due to the plurality of superlattice structures grown between the one or more first layers and the substrate.

In various embodiments, one or more buffer layers may be grown (directly) on the substrate, and the plurality of superlattice structures may be grown (directly) on the one or more buffer layers. Thus, the semiconductor structure may comprise one or more buffer layers between the plurality of superlattice structures and the substrate.

The one or more buffer layers may comprise any suitable buffers layers, e.g. depending on the nature of the substrate and the one or more first layers. In various embodiments, the one or more buffer layers may be formed from the same semiconductor material as the one or more first layers.

For example, where the substrate comprises a silicon substrate and the one or more first layers comprise a Gallium Antimonide (GaSb) layer, the one or more buffer layers may comprise a Gallium Antimonide (GaSb) layer, which may be grown on the silicon substrate, e.g. using an Aluminium Antimonide (AlSb) interfacial misfit (IMF) nucleation layer.

In these embodiments, the one or more buffer layers (e.g. the Gallium Antimonide (GaSb) layer) may be grown using a two-step growth procedure, e.g. wherein a first portion of the (GaSb) layer is grown at a first (substantially constant) temperature, and a second portion of the layer is then grown using one or more second temperatures, wherein the second temperature(s) is greater than the first temperature. In various embodiments, the second portion of the layer is grown using an (step-wise or continuously) increasing growth temperature. The first portion may be thicker than the second portion. This procedure has been shown to improve the layer quality.

Where the substrate comprises a silicon substrate and the one or more first layers comprise an Indium Arsenide (InAs) layer, the one or more buffer layers may comprise an Indium Arsenide (InAs) layer and/or a Gallium Antimonide (GaSb) layer.

Other buffer layers may be used, as appropriate.

The plurality of superlattice structures may together comprise a dislocation filter superlattice (DFSL) structure.

The plurality of superlattice structures may comprise any (plural) number of superlattice structures. The plurality of superlattice structures comprises at least an initial superlattice structure (which may be the superlattice structure of the plurality of superlattice structures that is nearest to the substrate), and one or more further superlattice structures which are between the initial superlattice structure and the one or more first semiconductor layers (and so may include the superlattice structure(s) nearest to the one or more first layers).

The one or more further superlattice structures may comprise at least a final superlattice structure, which may be the superlattice structure of the plurality of superlattice structures that is nearest to the one or more first layers, and may (or may not) comprise one or more intermediate superlattice structures which may be between the initial and final superlattice structures. The plurality of superlattice structures may comprise, for example, zero, one, two, three, four, five or more such intermediate superlattice structures between the initial and final superlattice structures.

In various particular embodiments, the plurality of superlattice structures comprises an initial superlattice structure, two intermediate superlattice structures, and a final superlattice structure.

Each superlattice structure of the plurality of superlattice structures may be formed (directly) adjacent to one or two of the other superlattice structures of the plurality of superlattice structures. However, in various particular embodiments, adjacent superlattice structures of the plurality of superlattice structures are separated from each other by a spacer layer. In various embodiments, a spacer layer is formed above (on the side nearest the one or more first layers) each superlattice structure. Thus, the semiconductor device may comprise a spacer layer above each superlattice structure.

Each spacer layer may have any suitable thickness, such as a few tens or hundreds of nanometres. The spacer layers may all have the same thickness, or the thicknesses of some or all of the spacer layers may be different. Each spacer layer may be formed from any suitable semiconductor material such as the same semiconductor material as the one or more first layers.

Other spacer layers may be used, as appropriate.

Each superlattice structure of the plurality of superlattice structures comprises a plurality of repeats of a semiconductor layer pair, i.e. a repeating pair of semiconductor layers (comprising a first layer and a second layer), with each layer of the pair being formed from a different semiconductor material.

In other words, each superlattice structure comprises a plurality of repeats of a first semiconductor material and a second different semiconductor material, where each repeat comprises a (single) first layer of the first semiconductor material and a (single) second layer of the second semiconductor material. As such, each superlattice structure may comprise multiple alternating layers of the first and second semiconductor materials.

Each superlattice structure of the plurality of superlattice structures may comprise any suitable (plural) number of repeats. Suitable numbers of repeats may be, for example, 1, 2, 3, 4, 5, 6, 7, 8, 9, 10, 11, 12, 13 or more repeats.

All of the superlattice structures of the plurality of superlattice structures may have the same number of repeats, but in various embodiments one or more or each superlattice structure of the plurality of superlattice structures has a different number of repeats to the other superlattice structure(s) of the plurality of superlattice structures.

All of the first layers of the first semiconductor material within a superlattice structure may have the same thickness as one another. Equally, all of the second layers of the second semiconductor material within a superlattice structure may have the same thickness as one another. As such, each semiconductor layer pair within a superlattice structure may have the same thickness as each other semiconductor layer pair within that superlattice structure.

Within each superlattice structure, the thickness of the first layers of the first semiconductor material may be the same as or different to the thickness of the second layers of the second semiconductor material.

Suitable thicknesses for each layer within each semiconductor layer pair are of the order of a few nanometres or tens of nanometres, such as between about 2 and 20 nm, or between about 4 and 15 nm. Similarly, suitable thicknesses for each semiconductor layer pair are of the order of a few nanometres or tens of nanometres, such as between about 5 and 40 nm, or between about 8 and 30 nm.

The first and second semiconductor materials of each semiconductor layer pair may comprise any suitable (different) semiconductor materials, such as any suitable (different) III-V compound semiconductor materials.

In various embodiments, one layer of each semiconductor layer pair (such the (each) first layer of the first semiconductor material) is formed from the same semiconductor material as the one or more first layers (i.e. the first semiconductor material may be the same semiconductor material as the material of the one or more first semiconductor layers).

Thus, one layer of each semiconductor layer pair (such as the (each) first layer) may be formed from Gallium Antimonide (GaSb), Gallium Arsenide (GaAs), Gallium Phosphide (GaP), Gallium Nitride (GaN), Gallium Arsenide Antimonide (GaAsSb), Gallium Indium Antimonide (GaInSb), Gallium Arsenide Phosphide (GaAsP), Gallium Indium Arsenide Antimonide (GaInAsSb), Indium Arsenide (InAs), Indium Phosphide (InP), Indium Arsenide Antimonide (InAsSb), Aluminium Antimonide (AlSb), or Aluminium Indium Antimonide (AlInSb), and the like.

The other layer of each semiconductor layer pair (such as the (each) second layer of the second semiconductor material) may be formed from any suitable (e.g. III-V compound) semiconductor material that is different to the first semiconductor material.

For example the other layer of each semiconductor layer pair (such as the (each) second layer) may be formed from Gallium Antimonide (GaSb), Gallium Arsenide (GaAs), Gallium Phosphide (GaP), Gallium Nitride (GaN), Gallium Arsenide Antimonide (GaAsSb), Gallium Indium Antimonide (GaInSb), Gallium Arsenide Phosphide (GaAsP), Gallium Indium Arsenide Antimonide (GaInAsSb), Indium Arsenide (InAs), Indium Phosphide (InP), Indium Arsenide Antimonide (InAsSb), Aluminium Antimonide (AlSb), or Aluminium Indium Antimonide (AlInSb), and the like.

Each semiconductor layer within each superlattice structure will have a strain-thickness product which will depend on (and is equal to the product of) the thickness of the semiconductor layer and the strain of the semiconductor layer.

The strain of each semiconductor layer will in turn depend on the lattice mismatch between the semiconductor layer and the semiconductor layer on which that layer is grown, and can be calculated using the equation:

$$ε = \frac{{α}_{i} - {α}_{s}}{{α}_{s}} \text{.100} \% ,$$

where αᵢ is the lattice constant of the layer, and αₛ is the lattice constant of the underlying layer.

In various embodiments, the plurality of superlattice structures is configured such that the strain of each second layer (of each semiconductor layer pair) in each superlattice structure of the plurality of superlattice structures is less than about 2%. This ensures that the strain of each second layer (within each semiconductor layer pair) can be accommodated by uniform elastic strain of the second layer, thereby ensuring high crystal quality.

In various embodiments, the plurality of superlattice structures is also configured such that the strain-thickness product of each second layer (of each semiconductor layer pair) in each superlattice structure of the plurality of superlattice structures is less than the so-called Mathews limit (as described further below). Thus in embodiments, the plurality of superlattice structures is configured such that the strain-thickness product of each second layer (of each semiconductor layer pair) in each superlattice structure of the plurality of superlattice structures is less than the Matthews limit as calculated using Equation 1.

In various embodiments, the plurality of superlattice structures is configured such that the strain-thickness product of each second layer (of each semiconductor layer pair) in each superlattice structure of the one or more further superlattice structures is greater than or equal to the strain-thickness product of each second layer (of each semiconductor layer pair) in superlattice structure(s) of the plurality of superlattice structures between that superlattice structure and the substrate. In other words, the plurality of superlattice structures is configured such that starting from the (initial) superlattice structure nearest to the substrate and going towards the superlattice structure nearest to the one or more first layer(s), the strain-thickness product of each second layer (of each semiconductor layer pair) in each superlattice structure is greater than or equal to the strain-thickness product of each second layer (of each semiconductor layer pair) in the preceding superlattice structure.

The plurality of superlattice structures may also be configured such that the strain-thickness product of each second layer (of each semiconductor layer pair) in at least one of the one or more further superlattice structures is greater than the strain-thickness product of each second layer (of each semiconductor layer pair) in the initial superlattice structure. This means that the plurality of superlattice structures may be configured such that the strain-thickness product of each second layer (of each semiconductor layer pair) in the superlattice structure nearest to the one or more first layers is greater than the strain-thickness product of each second layer (of each semiconductor layer pair) in the (initial) superlattice structure nearest to the substrate.

In various embodiments, the plurality of superlattice structures is configured such that the strain-thickness product of each second layer (of each semiconductor layer pair) in each superlattice structure of the one or more further superlattice structures is greater than the strain-thickness product of each second layer (of each semiconductor layer pair) in the preceding superlattice structure(s). In other words, in various embodiments, the plurality of superlattice structures is configured such that starting from the (initial) superlattice structure nearest to the substrate and moving towards the (final) superlattice structure nearest to the one or more first semiconductor layer(s), the strain-thickness product of each second layer (of each semiconductor layer pair) in each superlattice structure is greater than the strain-thickness product of each second layer (of each semiconductor layer pair) in (all of) the preceding superlattice structure(s). That is, adjacent superlattice structures of the plurality of superlattice structures are configured such that the strain-thickness product of each second layer (of each semiconductor layer pair) is greater in the superlattice structure of the adjacent superlattice structures nearest to the one or more first layers.

As will be described in more detail below, the Applicant has found that increasing the strain-thickness product of each second layer (of each semiconductor layer pair) of the superlattice structures in this manner has the effect of enhancing the filtering effect of the plurality of superlattice structures. The use of this structure accordingly allows high crystalline quality semiconductor layers to be formed.

Each semiconductor layer pair (i.e. each repeat of each superlattice structure) will also have a strain-thickness product, which depends on (and is equal to the product of) the thickness of the semiconductor layer pair (i.e. the thickness of the repeat) and the strain of the semiconductor layer pair (i.e. the strain of the repeat).

The strain of each semiconductor layer pair will in turn depend on the lattice mismatch between the semiconductor layer pair and the semiconductor layer on which the layer pair is grown, and can be calculated using the equation:

$${ε}_{pl} = \frac{( \frac{{α}_{1} . {h}_{1} + {α}_{2} . {h}_{2}}{{h}_{pl}} ) - {α}_{s}}{{α}_{s}} ,$$

where α₁ is the lattice constant of the first layer of the semiconductor layer pair, α₂ is the lattice constant of the second layer of the semiconductor layer pair, αₛ is the lattice constant of the semiconductor material on which the layer pair is grown, h₁ is the thickness of the first layer of the semiconductor layer pair, h₂ is the thickness of the second layer of the semiconductor layer pair, and hₚₗ(=h₁+h₂) is the (total) thickness of the semiconductor layer pair.

In various embodiments, the plurality of superlattice structures is configured such that the strain of each semiconductor layer pair in each superlattice structure of the plurality of superlattice structures is less than about 2%. This again ensures high crystal quality.

In various embodiments, the plurality of superlattice structures is also configured such that the strain-thickness product of each semiconductor layer pair in each superlattice structure of the plurality of superlattice structures is less than the so-called Mathews limit. Thus in embodiments, the plurality of superlattice structures is configured such that the strain-thickness product of each semiconductor layer pair in each superlattice structure of the plurality of superlattice structures is less than the Matthews limit as calculated using Equation 1.

The plurality of superlattice structures is configured such that the strain-thickness product of semiconductor layer pairs in each superlattice structure of the one or more further superlattice structures is greater than or equal to the strain-thickness product of semiconductor layer pairs in superlattice structure(s) of the plurality of superlattice structures between that superlattice structure and the substrate. In other words, the plurality of superlattice structures is configured such that starting from the (initial) superlattice structure nearest to the substrate and going towards the superlattice structure nearest to the one or more first layer(s), the strain-thickness product of semiconductor layer pairs in each superlattice structure is greater than or equal to the strain-thickness product of semiconductor layer pairs in the preceding superlattice structure.

The plurality of superlattice structures is also configured such that the strain-thickness product of semiconductor layer pairs in at least one of the one or more further superlattice structures is greater than the strain-thickness product of semiconductor layer pairs in the initial superlattice structure. This means that the plurality of superlattice structures is configured such that the strain-thickness product of semiconductor layer pairs in the superlattice structure nearest to the one or more first layers is greater than the strain-thickness product of semiconductor layer pairs in the (initial) superlattice structure nearest to the substrate.

In various embodiments, the plurality of superlattice structures is configured such that the strain-thickness product of semiconductor layer pairs in each superlattice structure of the one or more further superlattice structures is greater than the strain-thickness product of semiconductor layer pairs in the preceding superlattice structure(s).

In other words, in various embodiments, the plurality of superlattice structures is configured such that starting from the (initial) superlattice structure nearest to the substrate and moving towards the (final) superlattice structure nearest to the one or more first semiconductor layer(s), the strain-thickness product of semiconductor layer pairs in each superlattice structure is greater than the strain-thickness product of semiconductor layer pairs in (all of) the preceding superlattice structure(s). That is, adjacent superlattice structures of the plurality of superlattice structures are configured such that the strain-thickness product of semiconductor layer pairs is greater in the superlattice structure of the adjacent superlattice structures nearest to the one or more first layers.

As will be described in more detail below, the Applicant has found that increasing the strain-thickness product of the semiconductor layer pairs of the superlattice structures in this manner has the effect of enhancing the filtering effect of the plurality of superlattice structures. The use of this structure accordingly allows high crystalline quality semiconductor layers to be formed.

The strain-thickness product of semiconductor layer pairs can be increased between adjacent superlattice structures of the plurality of superlattice structures in any suitable manner.

In various particular embodiments, one or both of the strain of the semiconductor layer pairs and the thickness of the semiconductor layer pairs is increased between adjacent superlattice structures.

Thus, in various embodiments, the plurality of superlattice structures is configured such that the thickness and/or strain of semiconductor layer pairs in each superlattice structure of the one or more further superlattice structures is greater than or equal to the thickness and/or strain of semiconductor layer pairs in superlattice structure(s) of the plurality of superlattice structures between that superlattice structure and the substrate, and the plurality of superlattice structures is configured such that the thickness and/or strain of semiconductor layer pairs in at least one of the one or more further superlattice structures is greater than the thickness and/or strain of semiconductor layer pairs in the initial superlattice structure.

In various embodiments, the plurality of superlattice structures is configured such that the thickness and/or strain of semiconductor layer pairs in each superlattice structure of the one or more further superlattice structures is greater than the thickness and/or strain of semiconductor layer pairs in the preceding superlattice structure(s).

The semiconductor layer pair thickness can be increased between each superlattice structure by increasing one or both of the thickness of each first layer (of each semiconductor layer pair) and the thickness of each second layer (of each semiconductor layer pair) between adjacent superlattice structures.

Thus, in various embodiments, the plurality of superlattice structures is configured such that in each superlattice structure of the one or more further superlattice structures: (i) the thickness of each first layer (of each semiconductor layer pair) is greater than the thickness of each first layer (of each semiconductor layer pair) in the preceding superlattice structure; and/or (ii) the thickness of each second layer (of each semiconductor layer pair) is greater than the thickness of each second layer (of each semiconductor layer pair) in the preceding superlattice structure.

The semiconductor layer pair strain can be increased between each superlattice structure by altering the semiconductor material and/or by altering the composition of the semiconductor material, of one or both of each first and/or second layer (of each semiconductor layer pair) between adjacent superlattice structures. In various particular embodiments, the semiconductor layer pair strain is increased between adjacent superlattice structures by altering the semiconductor material and/or by altering the composition of the semiconductor material, of each second layer (of each semiconductor layer pair) between adjacent superlattice structures.

For example, where each second layer (of each semiconductor layer pair) is formed from a ternary, quaternary (and higher order) compound semiconductor, the semiconductor layer pair strain can be increased between each superlattice structure by altering the composition (i.e. mole fraction) of two constituents of the ternary, quaternary (etc.) compound semiconductor (as will be described further below).

Thus, in various embodiments, the plurality of superlattice structures is configured such that in each superlattice structure of the one or more further superlattice structures: (i) the semiconductor material and/or the composition of the semiconductor material of each first layer (of each semiconductor layer pair) is different to the semiconductor material and/or the composition of the semiconductor material of each first layer (of each semiconductor layer pair) in the preceding superlattice structure; and/or (ii) the semiconductor material and/or the composition of the semiconductor material of each second layer (of each semiconductor layer pair) is different to the semiconductor material and/or the composition of the semiconductor material of each second layer (of each semiconductor layer pair) in the preceding superlattice structure.

Each superlattice structure of the plurality of superlattice structures will also have a strain-thickness product, which depends on (and is equal to the product of) the total thickness of the superlattice structure and the strain of the superlattice structure. The total thickness of the superlattice structure is equal to the number of semiconductor layer pairs in the superlattice structure multiplied by the thickness of a (each) semiconductor layer pair of the superlattice structure.

The strain of each superlattice structure will in turn depend on the lattice mismatch between the superlattice structure and the semiconductor layer on which that superlattice structure is grown, and is equal to the strain of each semiconductor layer pair of that superlattice structure.

In various embodiments, the plurality of superlattice structures is configured such that the strain of each superlattice structure of the plurality of superlattice structures is less than about 2%. This again ensures that high crystal quality.

In various embodiments, the plurality of superlattice structures is also configured such that the strain-thickness product of each superlattice structure of the plurality of superlattice structures is less than about 0.8 nm. As will be described further below, the Applicant has recognised that superlattice structure strain-thickness products above this value can lead to defect generation.

The plurality of superlattice structures may also be configured such that the strain-thickness product of each superlattice structure of the plurality of superlattice structures is greater than about 0.6 nm.

In various embodiments, the plurality of superlattice structures is configured such that the strain-thickness product of each superlattice structure of the one or more further superlattice structures is greater than or equal to the strain-thickness product of superlattice structure(s) of the plurality of superlattice structures between that superlattice structure and the substrate. In other words, the plurality of superlattice structures is configured such that starting from the (initial) superlattice structure nearest to the substrate and going towards the superlattice structure nearest to the one or more first layer(s), the strain-thickness product of each superlattice structure is greater than or equal to the strain-thickness product of the preceding superlattice structure.

The plurality of superlattice structures may also be configured such that the strain-thickness product of at least one of the one or more further superlattice structures is greater than the strain-thickness product of the initial superlattice structure. This means that the plurality of superlattice structures may be configured such that the strain-thickness product of the superlattice structure nearest to the one or more first layers is greater than the strain-thickness product of the (initial) superlattice structure nearest to the substrate.

In various embodiments, the plurality of superlattice structures is configured such that the strain-thickness product of each superlattice structure of the one or more further superlattice structures is greater than the strain-thickness product of the preceding superlattice structure(s). In other words, in various embodiments, the plurality of superlattice structures is configured such that starting from the (initial) superlattice structure nearest to the substrate and moving towards the (final) superlattice structure nearest to the one or more first semiconductor layer(s), the strain-thickness product of each superlattice structure is greater than the strain-thickness product of (all of) the preceding superlattice structure(s). That is, adjacent superlattice structures of the plurality of superlattice structures are configured such that the strain-thickness product is greater in the superlattice structure of the adjacent superlattice structures nearest to the one or more first layers.

As will be described in more detail below, the Applicant has found that increasing the strain-thickness product of the superlattice structures in this manner has the effect of enhancing the filtering effect of the plurality of superlattice structures. The use of this structure accordingly allows high crystalline quality semiconductor layers to be formed.

The strain-thickness product of superlattice structures can be increased between adjacent superlattice structures of the plurality of superlattice structures in any suitable manner.

In various particular embodiments, one or both of the strain of the superlattice structure and the thickness of the superlattice structure is increased between adjacent superlattice structures.

Thus, in various embodiments, the plurality of superlattice structures is configured such that the thickness and/or strain of each superlattice structure of the one or more further superlattice structures is greater than or equal to the thickness and/or strain of superlattice structure(s) of the plurality of superlattice structures between that superlattice structure and the substrate, and the plurality of superlattice structures is configured such that the thickness and/or strain of at least one of the one or more further superlattice structures is greater than the thickness and/or strain of the initial superlattice structure.

In various embodiments, the plurality of superlattice structures is configured such that the thickness and/or strain of each superlattice structure of the one or more further superlattice structures is greater than the thickness and/or strain of the preceding superlattice structure(s).

The superlattice structure thickness can be increased between each superlattice structure by increasing the thickness of each semiconductor layer pair between adjacent superlattice structures.

It would also be possible to increase the superlattice structure thickness between each superlattice structure by increasing the number of repeats of semiconductor layer pairs in each superlattice structure between adjacent superlattice structures. However, in various particular embodiments the number of repeats of semiconductor layer pairs in each superlattice structure is constant or decreases between adjacent superlattice structures (and the increase in strain and/or semiconductor layer pair thickness between adjacent superlattice structures is relied upon to increase the strain-thickness product between adjacent superlattice structures).

Thus, in various embodiments, the plurality of superlattice structures is configured such that the number of repeats in each superlattice structure of the one or more further superlattice structures is less than or equal to the number of repeats in superlattice structure(s) of the plurality of superlattice structures between that superlattice structure and the substrate. The plurality of superlattice structures may be configured such that the number of repeats in at least one of the one or more further superlattice structures is less than the number of repeats in the initial superlattice structure.

In various embodiments, the plurality of superlattice structures is configured such that the number of repeats in each superlattice structure of the one or more further superlattice structures is greater than the number of repeats in the preceding superlattice structure(s).

The superlattice strain can be increased between each superlattice structure by altering the semiconductor layer pair strain between each superlattice structure in the manner described above.

The semiconductor structure should (and in various embodiments does) comprise a semiconductor heterostructure that includes the layers described above. As such, the semiconductor structure may comprise plural semiconductor layers (i.e. that are epitaxially grown together), including each of the layers described above.

The semiconductor structure may form part of a semiconductor device. Thus, according to another aspect there is provided a semiconductor device comprising the semiconductor structure described above. According to another aspect there is provided a method of forming a semiconductor device, the method comprising forming the semiconductor structure described above.

The semiconductor device may comprise one or more second semiconductor layers, such as one or more III-V compound semiconductor layers, which may be (directly) adjacent to (grown on) the one or more first semiconductor layers. The one or more second layers may comprise one or more active layers of the semiconductor device. Since, as described above, the one or more first (epi-)layers will have a particularly low defect density, the one or more second active layers will also have a high crystalline quality, thereby improving the operation of the semiconductor device.

The semiconductor device may be any suitable device, such as a light-emitting device (e.g. a light emitting diode (LED), diode laser, vertical cavity surface emitting laser (VCSEL), etc.), a light-detecting device such as a detector (e.g. photodetector, etc.), and/or an electronic device (e.g. a transistor, memory, etc.).

Where the semiconductor device comprises a light-emitting device or a light-detecting device, the semiconductor device may be sensitive to and/or emit light in any suitable range, such as for example the mid-infrared range (around 2 to 5 μm).

Certain preferred embodiments of the present disclosure will now be described in greater detail, by way of example only and with reference to the following figures, in which:

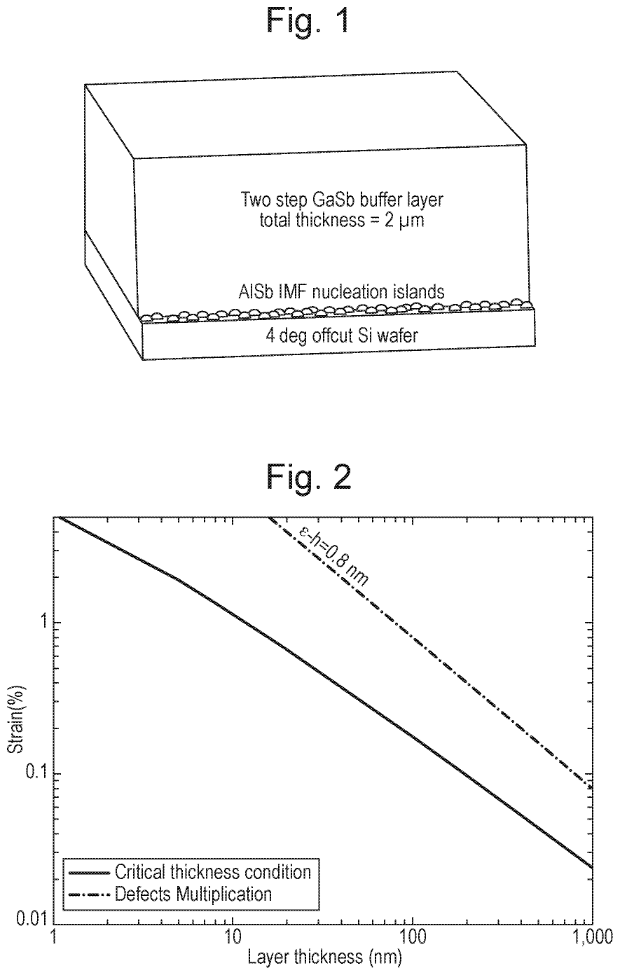

FIG. 1 is a representation of a two-step GaSb buffer layer grown on a Si wafer;

FIG. 2 is an illustration of misfit strain as a function of layer thickness;

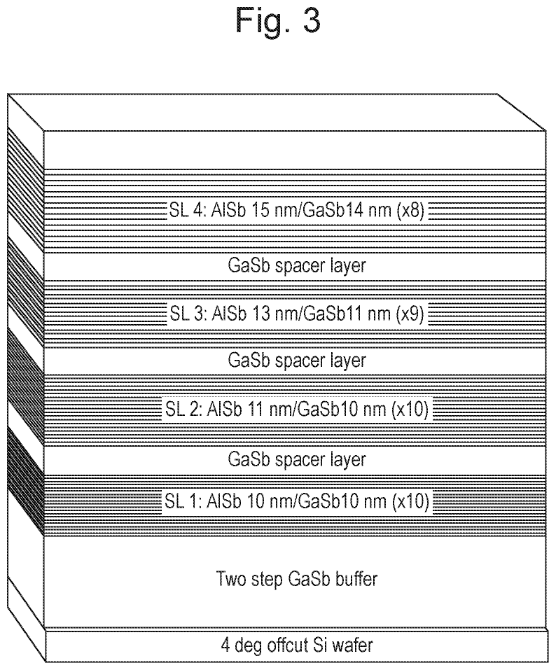

FIG. 3 is a schematic illustration of a AlSb/GaSb DFSL structure in accordance with various embodiments;

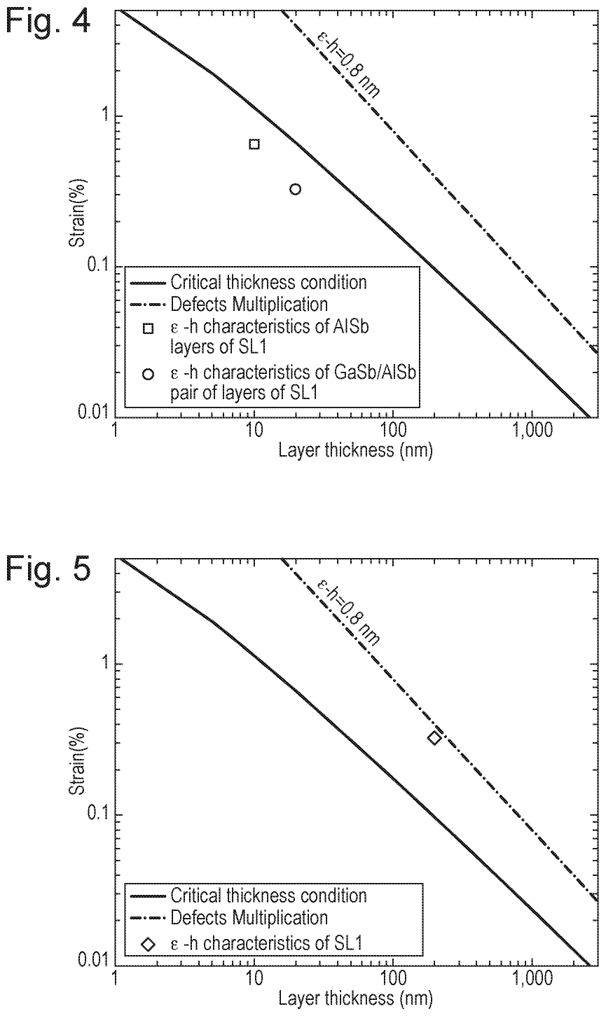

FIG. 4 is a schematic illustration of the strain-thickness characteristics of the AlSb layer and the GaSb/AlSb layer pair of the first superlattice of the structure of FIG. 3;

FIG. 5 is a schematic illustration of the strain-thickness characteristics of the first GaSb/AlSb superlattice of the structure of FIG. 3;

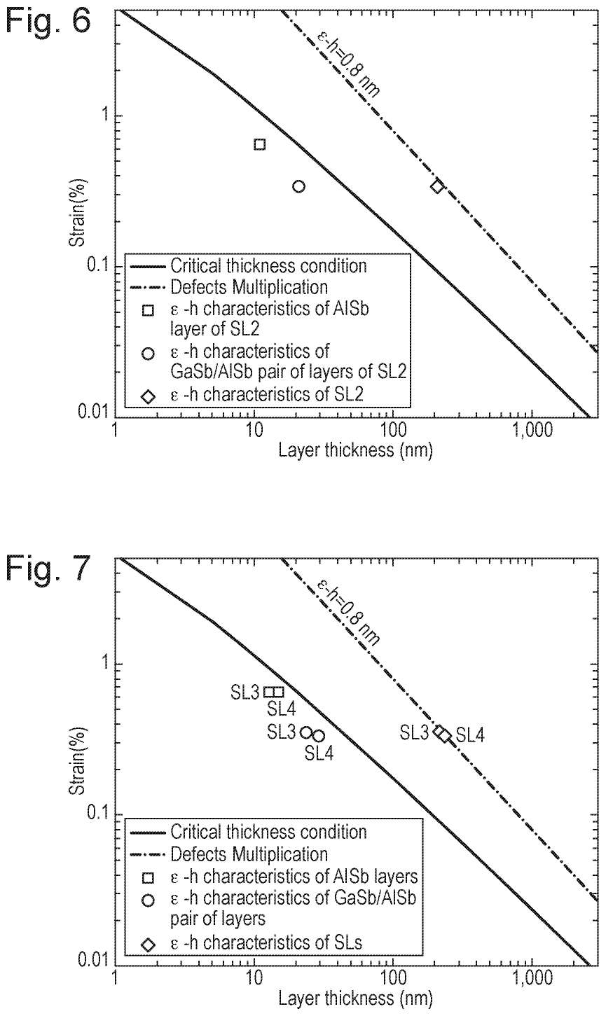

FIG. 6 is a schematic illustration of the strain-thickness characteristics of the AlSb layer, the AlSb/GaSb layer pair and the total superlattice of the second dislocation filter structure of the structure of FIG. 3;

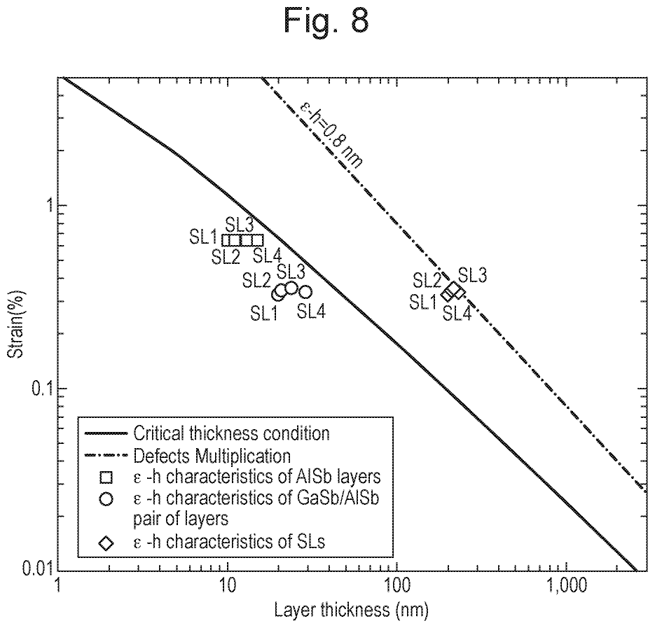

FIG. 7 is a schematic illustration of the strain-thickness characteristics of the AlSb layer, the GaSb/AlSb layer pairs and the total superlattice of the third and fourth dislocation filter structures of the structure of FIG. 3; FIG. 8 is a graphical representation of the strain-thickness characteristics of the AlSb layer, the AlSb/GaSb layer pairs and the SL of all the AlSb/GaSb dislocation filter structures of the structure of FIG. 3;

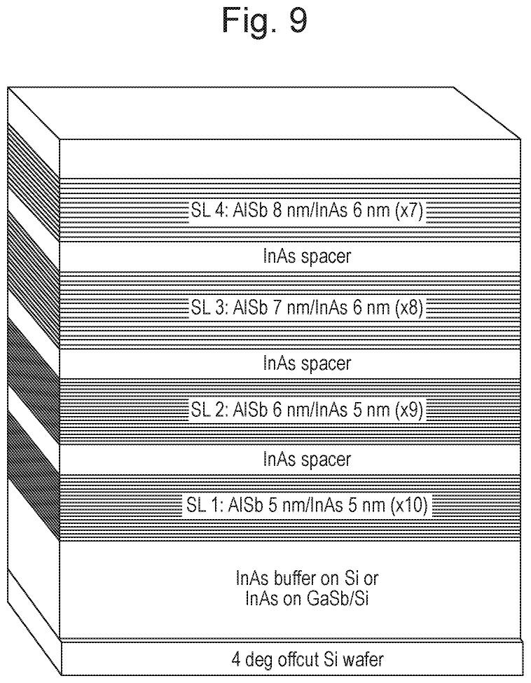

FIG. 9 is a schematic illustration of a InAs/AlSb DFSL structure in accordance with various embodiments;

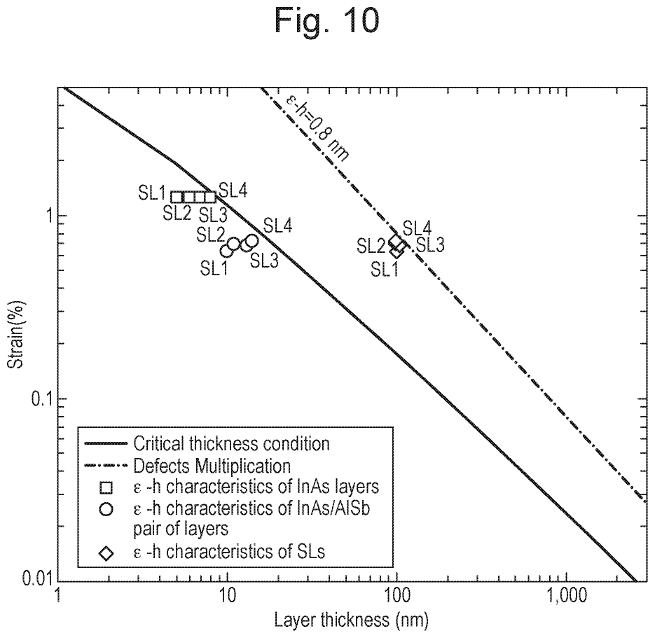

FIG. 10 is a graphical representation of the strain-thickness characteristics of the AlSb layer, the InAs/AlSb layer pairs and the superlattice of each of the four InAs/AlSb dislocation filter structures of the structure of FIG. 9;

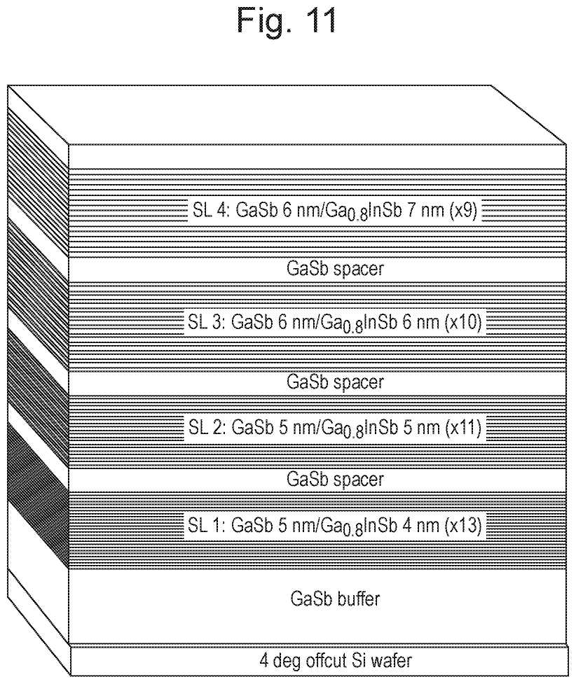

FIG. 11 is a schematic illustration of a GaSb/Ga_{0.8}In_{0.2}Sb DFSL structure in accordance with various embodiments;

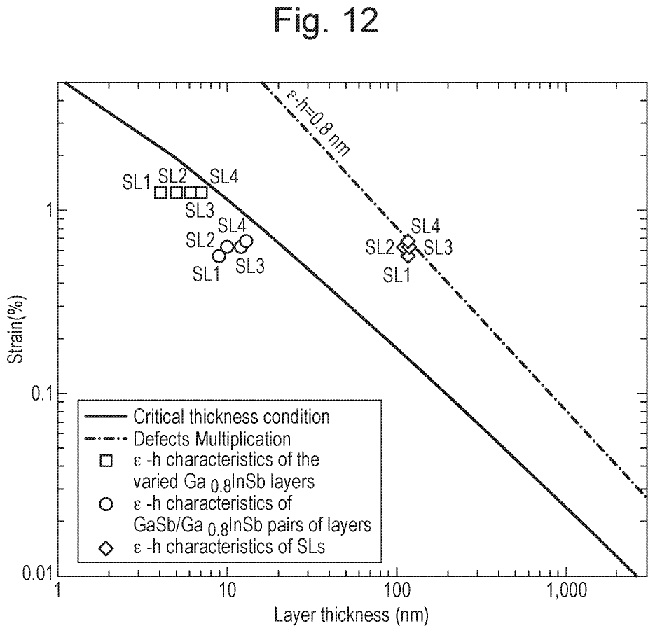

FIG. 12 is a graphical representation of the strain-thickness characteristics of the GaSb/Ga_{0.8}In_{0.2}Sb layers, the GaSb/GaSb/Ga_{0.8}In_{0.2}Sb layer pairs and the four GaSb/Ga_{0.8}In_{0.2}Sb superlattices of the structure of FIG. 11;

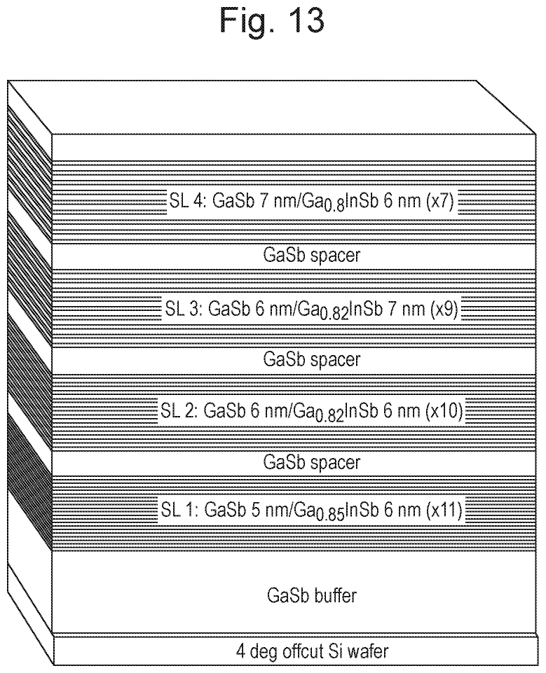

FIG. 13 is a schematic illustration of a GaSb/GaₓIn₍₁₋ₓ₎Sb DFSL structure in accordance with various embodiments; and

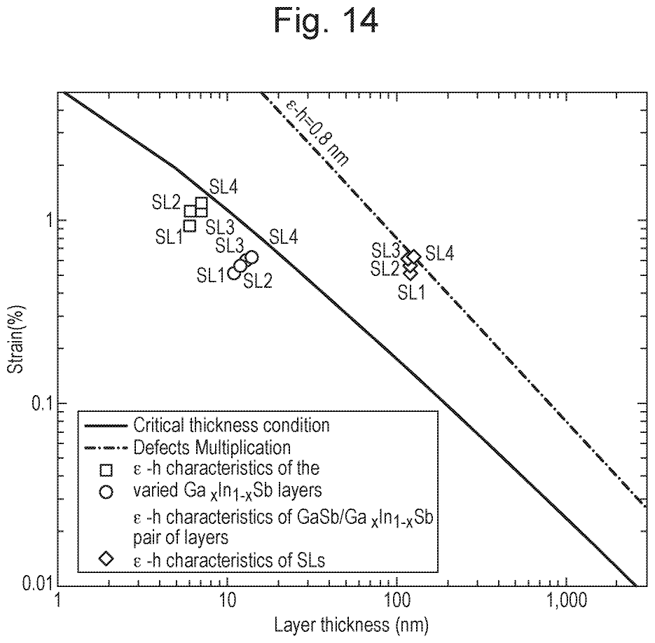

FIG. 14 is a graphical representation of the strain-thickness characteristics of the varied GaₓIn₍₁₋ₓ₎Sb layers, the GaSb/GaₓIn₍₁₋ₓ₎Sb layer pairs and the four GaSb/GaₓIn₍₁₋ₓ₎Sb superlattices of the structure of FIG. 13.

Heteroepitaxial growth of thin films with high lattice mismatch to the underlying substrate leads to the formation of threading dislocations, which deteriorate the crystalline quality of the epilayer and hinders the performance of electrical devices.

For example, direct integration of gallium antimonide (GaSb) on group IV wafers, such as silicon (Si), is an attractive root for reducing manufacturing costs and developing fully integrated lab-on-chip mid-infrared (MIR) Si photonic circuits.

However, the large lattice mismatch (˜12%) is challenging and direct epitaxial growth results in a large density (≥10¹⁰cm⁻²) of threading dislocations and planar defects.

It has been previously reported that the growth of GaSb on a Si wafer using a thin aluminium antimonide (AlSb) nucleation layer enables the confinement of dislocations at the interface via the formation of a network of interfacial misfit dislocation (IMF) arrays. However, a substantial number of defects remain in the epilayer, which propagate from the lower parts of the epitaxial layer to the top, leading to a surface dislocation density of the order of 10⁹ cm⁻². This value is approximately four orders of magnitude higher than the estimated defect limit of ˜10⁵ cm⁻² for GaSb integrated on Si.

Various embodiments provide a new method for growing high crystalline quality epilayers on a mismatched substrate using a series of strained dislocation filters. The dislocation filter layers act as blocking barriers to the vertical propagation of threading dislocations, leading to a surface defect density of the order of 10⁶ cm⁻².

Previous work on the heteroepitaxial integration of high quality GaSb on Si was based on the growth of a thick GaSb layer on 4 degrees offcut Si wafers using a 17 monolayer (ML) thin AlSb IMF nucleation layer and a two-temperature step growth procedure. The use of misoriented Si wafers suppresses the formation of planar defects such as antiphase domains (APDs).

FIG. 1 is a representation of the two-step GaSb buffer layer. The two-step growth technique comprises the deposition of a 1.5 μm thick GaSb layer using a growth temperature of 487° C., followed by the growth of another 500 nm of GaSb while gradually increasing the growth temperature up to 515° C.

This procedure significantly improves the layer quality, resulting in a surface dislocation density of 2×10⁸ cm⁻². A variety of antimonide-based semiconductor material systems can then be grown on top of the buffer layer, based on the application and e.g. the desired operation wavelength.

Initially, the dislocation density is expected to reduce with increasing buffer layer thickness. This is due to a reaction between threading dislocations as they approach an area where interaction is energetically favorable. However, previous reports have shown that for a constantly incremental change in the thickness of the buffer layer, the probability of two dislocations being placed in the same interaction area is significantly decreased. Therefore, reducing the dislocation density lower than the order of 10⁸ cm⁻² using a simple buffer layer is very unlikely.

Thus, it has been recognised that lateral overgrowth of dislocation filter superlattices (SL) comprising alternating semiconductor strained layers is important to further decrease the number of threading dislocations reaching the surface of the structure and/or the active region of a device. The additional interfacial misfit strain promotes movement and glide of threading dislocations, which triggers defect recombination. This is considered to be the principal method to achieve defects densities of the order of 10⁶ cm⁻² or lower, greatly reduced compared to what is feasible using only thick buffer layers.

Strained layer dislocation filter structures usually comprise a number of superlattices separated by spacer layers. Each superlattice comprises a pair of layers (a layer pair), layer 1 of thickness h1 and layer 2 of thickness h2, which is repeated t times, where t=1,2,3 etc. Spacer layers can be grown after each superlattice structure to help relieve the total residual strain introduced by the alternative strained layers of the underlying superlattice. A key advantage of a superlattice over a bulk strained layer is that the interfacial misfit strain values are significantly lower than that present at the interface with the substrate and can be used repeatedly; thus increasing the effectiveness of dislocation blocking. The interfacial misfit strain generated between layers of alternative materials can be used to force moving and bowing of threading dislocations. A misfit strain of up to 1.5-2% can be accommodated by uniform elastic strain of the epilayer. However, if the strain introduced during the epitaxial growth is sufficiently large or if the epilayer exceeds a critical thickness, further defects can be generated or start to move by glide in order to relieve the strain.

The concept of the critical thickness is described by the Matthews equation:

$$ϵ = \frac{b}{2 {h}_{c} cos ( λ )} ( \frac{1}{10} + \frac{1}{4 π} \frac{1 - v {cos}^{2} ϑ}{1 - v} ln ( \frac{{h}_{c}}{b} ) ) , \qquad ( 1 )$$

where ε is the misfit strain, h_{c} is the critical thickness, λ is the angle between the slip direction and the direction of the layer plane which is perpendicular to the intersection of the slip plane and the surface, b is the magnitude of the Burger vector, v is the Poisson ratio, and ϑ is the angle between the dislocation line and its Burger vector.

The misfit strain of the layer is given by the equation:

$$ε = \frac{{α}_{i} - {α}_{s}}{{α}_{s}} \text{.100} \% , \qquad ( 2 )$$

where αᵢ is the lattice constant of the layer, and αₛ is the lattice constant of the substrate, the buffer layer or the spacer layer of a superlattice.

In general, the thickness of the layer is significantly lower than the underlying thick material layer (substrate, buffer or spacer). For a film grown on a (001) film plane, dislocations with Burger vector of the type

$$\frac{a}{2} < 110 >$$

are assumed. The magnitude of the Burger vector is given by the equation:

$$\vert b \vert = \frac{a}{2} \sqrt{{h}^{2} + {k}^{2} + {l}^{2}} . \qquad ( 3 )$$

For antimonide (Sb) materials (GaSb, InAs, AlSb binary and their alloys), also known as the group of 6.1 Å III-V semiconductors, an average lattice constant of α=6.1 Å, and a Poisson ratio of v˜0.33 is assumed. The magnitude of the Burger vector is approximately 0.43 nm, while cos

$$( λ ) = \frac{1}{\sqrt{2}} and cos ( ϑ ) = \frac{1}{2} .$$

For arsenide (As), nitride (N) and phosphide (P) materials the lattice constant, the Poisson ratio and the Burger vector should be changed accordingly.

The critical thickness predictions from equation (1) for 6.1 Å semiconductor epitaxial layers grown on (001) films are shown in FIG. 2.

FIG. 2 is an illustration of the misfit strain as a function of layer thickness. The solid line shows the variation of the critical thickness with misfit strain predicted for antimonide semiconductors.

As a general rule, for layers with strain-thickness characteristics below the Matthews limit (black line), the elastic strain is less than that necessary to form defects, and new threading dislocations do not spontaneously advance. Thus, it is expected that for ε·h placed below and up to the critical thickness line, the elastic misfit strain is easily accommodated via plastic deformation of the layer. However, for superlattice layers below this limit, blocking of pre-existent dislocations is still possible due to dislocation bending or interaction.

Increasing the layer thickness well beyond the critical value can lead to defect generation to accommodate the misfit strain. However, several reports have indicated that even for strain-thickness products higher than by up to 20% of the critical values calculated by the Matthews model, generation of new dislocations may not take place.

Hence, it is possible to grow epitaxial layers beyond the critical layer thickness using suitable growth conditions. In various embodiments, the values predicted by the Matthews model are taken as the minimum critical thickness values to be certain of ensuring no defect generation.

Eventually, as the critical thickness is well exceeded, it becomes energetically favourable for dislocation generation to become active. Initially, strain relaxation and defect generation is slow. However, for a thickness far greater than the critical value, the effective strain is sufficient that the density of dislocations increases exponentially until the effective strain is greatly decreased. For this defect multiplication mechanism to be activated, the thickness of the layer must be sufficiently thick for dislocation loops or circles to be generated. Thus, layer thicknesses several times that of the critical thickness are required.

Various embodiments use a dislocation multiplication limit of ε·h˜0.8nm (shown by the dashed-dot line in FIG. 2). If the strain-thickness characteristics of a layer are placed above the dashed-dot line of FIG. 2, then more dislocation sources are activated and the dislocation density is substantially increased. In other words, dislocation multiplication is activated for strain-thickness product values higher than 0.8 nm.

For strained layers with strain-thickness characteristics below and as close as possible to the ε·h=0.8 nm limit line, high-quality layers can be obtained with low defect densities.

Based on the above considerations, it can be seen that the strain-thickness product provides an important role in the strain relaxation mechanisms, and can be used as an important parameter to design effective dislocation filter superlattices. The main goal is to remove threading dislocations as efficiently as possible whilst not generating new sources or multiplication.

According to various embodiments, the following design rules are provided to enable the formation of effective dislocation filter (DFSL) structures:

(i) The Matthews condition (Equation 1) presented earlier is defined as the thickness limit which completely ensures the suppression of defect generation when growing strained epitaxial layers, whilst allowing bending of defects at the interfaces. Thus, the individual thickness of the layers (hᵢ where i=1 or 2) should be lower than the corresponding Matthews critical thickness. The misfit strain of the layers is calculated using Equation 2.

(ii) Each superlattice (SL) comprises several repeats of a layer pair. It is assumed that the layer pair operates as a single layer with thickness:

hₚₗ=h₁+h₂. (4)

The strain of the layer pair can be calculated using equation:

$${ε}_{pl} = \frac{( \frac{{α}_{1} . {h}_{1} + {α}_{2} . {h}_{2}}{{h}_{pl}} ) - {α}_{s}}{{α}_{s}} , \qquad ( 5 )$$

where αᵢ, i=1 or 2, is the lattice constant of the semiconductor layer. The thickness hₚₗ of the layer pair must also follow the Matthew model for the calculated strain.

(iii) To avoid significantly increasing the total strain εₚₗ, which might lead to the growth of incoherently strained layers, the strain of the layer pair should also be lower than 2%.

(iv) The strain-thickness product of the layer pair (εₚₗ·hₚₗ) should increase for each SL structure when moving towards the top of the structure. Higher strain-thickness product values for the layer pair can be achieved by increasing the strain (εᵢ) and/or the thickness (hᵢ) of the layers when moving towards the top SLs of the structure.

(v) The dislocation filter superlattices are considered to behave as a single layer with total thickness given by:

h_{SL}=hₚₗ×t, (5)

where t is the number of iterations, while the SL strain will be equal to εₚₗ. As such, the number of iterations is chosen so that the strain-thickness characteristics of the superlattice is placed below the multiplication limit to avoid multiplication of defects. As a result, the strain-thickness product of each SL should be lower than 0.8, i.e. ε_{SL}·h_{SL}<0.8 nm.

(vi) The total thickness of each SL and the number of iterations should be chosen so that the strain-thickness product of the SL (ε_{SL}·h_{SL}) increases when moving towards the top SLs in the structure.

(vii) If all the SLs are placed very close to the 0.8 nm limit, then the total net strain in the structure might be too high leading to generation of defects. Therefore, only the strain-thickness characteristics of the top SLs in the filter structure should be placed closer to the 0.8 nm limit.

In general, it is anticipated that moving towards the upper parts of the structure, the dislocation density is significantly reduced by the blocking effect of the preceding SL structures. As a result, the spatial separation between the dislocations will increase, thereby reducing the probability of defect interaction.

In order to further increase dislocation sweeping by the interfaces and enhance the motion of dislocations to promote their intersection and thus reduce their number, thicker layers and/or higher strain-thickness products are used when proceeding towards the top of the structure. This also implies that h_{plSL1}<h_{plSL2}< . . . <h_{plSLn}, and ε_{SL1}·h_{SL1}<ε_{SL2}·h_{SL2}< . . . <ε_{SLn}·h_{SLn}≤0.8 nm, where n=1,2,3 etc.

It is important to note that, apart from the demand of thicker layers and/or higher strain-thickness product as a means to significantly increase the effectiveness of the filter SL structure, the use of several superlattices with maximum ε_{SL}·h_{SL} product values (ε_{SL}·h_{SL}≈0.8 nm) will lead to failure of the filters and the total structure/device. Therefore, it is important that the strain-thickness product is built up gradually when proceeding with the growth.

Using the above limitations, a variety of possible dislocation filter structures can be designed using different III-V semiconductor material systems (such as GaSb/AlSb, InAs/AlSb and GaInSb/GaSb).

The following present in detail the characteristics of four Sb-based dislocation filter structures in accordance with various embodiments.

### GaSb/AlSb Dislocation Filter Superlattice for Growing GaSb Buffer Layers

First, a GaSb/AlSb dislocation filter structure design is presented using a series of GaSb and AlSb layers with variable thicknesses. The misfit strain of an AlSb layer grown on GaSb is equal to 0.649%, which was calculated using the following equation (equation 2):

$$ε = \frac{{α}_{AlSb} - {α}_{GaSb}}{{α}_{GaSb}} \text{.100} \% ,$$

where α_{AlSb}=0.61355 nm and α_{GaSb}=0.609593 nm, the lattice constant of AlSb and GaSb respectively.

The strain is significantly lower than 2%, so that the thin AlSb layers can be elastically grown on GaSb. According to the Matthews critical thickness rule, for a strain of 0.649%, the critical thickness h_{c} up to which the defects generation can be avoided is approximately 20 nm.

Following the rules described earlier, the GaSb/AlSb dislocation filter structure design comprises four SLs, each one with varied AlSb, GaSb and total SL thickness. As shown in FIG. 3, for each adjacent superlattice, the thickness of the layers and the strain-thickness product of the SLs increases.

Table I summarizes the characteristics of the four GaSb/AlSb superlattices used in the structure.

TABLE I
Strain and thickness characteristics of the GaSb/AlSb dislocation filter
superlattice structure comprising four individual superlattices.

| | | | | | Theoretical |
|---|---|---|---|---|---|
| | SL 1 | SL2 | SL3 | SL4 | Limitations |
| h_{GaSb} (nm) | 10 | 10 | 11 | 14 | |
| h_{AlSb} (nm) | 10 | 11 | 13 | 15 | h_{c}_{_{AlSb}} = 20 nm |
| ε_{AlSb} (%) | 0.649 | 0.649 | 0.649 | 0.649 | 2% |
| ε_{AlSb} · h_{AlSb} | 0.0649 | 0.0714 | 0.0844 | 0.0974 | |
| (nm) | | | | | |
| hₗₚ (nm) | 20 | 21 | 24 | 29 | |
| εₗₚ (%) | 0.3248 | 0.3400 | 0.3516 | 0.3357 | 2% |
| εₗₚ · hₗₚ (nm) | 0.0650 | 0.0714 | 0.0844 | 0.09094 | |
| Iterations | 10 | 10 | 9 | 8 | |
| h_{SL} (nm) | 200 | 210 | 216 | 232 | |
| ε_{SL} (%) | 0.3248 | 0.3400 | 0.3516 | 0.3357 | 2% |
| ε_{SL} · h_{SL} (nm) | 0.6496 | 0.7140 | 0.7595 | 0.7788 | Multiplication |
| | | | | | limit = 0.8 |

Based on the results presented in Table I, the four superlattices satisfy the rules described above. In further detail:

(i) SL1: GaSb 10 nm/AlSb 10nm, 10 iterations.

The thickness of the AlSb layers is h_{AlSb}=10 nm, while the total thickness of the GaSb/AlSb layer pair is:

hₗₚ=h_{AlSb}+h_{GaSb}=10+10=20 nm.

The strain values of the AlSb layer and the GaSb/AlSb layer pair are:

$$ε = \frac{{α}_{AlSb} - {α}_{GaSb}}{{α}_{GaSb}} = \frac{0.61355 - 0.609593}{0.609593} = 0.00649 \to 0.649 \% ,$$

$$and$$

$${ε}_{lp} = \frac{( \frac{{α}_{AlSb} . {h}_{AlSb} + {α}_{GaSb} . {h}_{GaSb}}{{h}_{lp}} ) - {α}_{s}}{{α}_{GaSb}} = \frac{( \frac{0.61355 \text{.10} + 0.609593 \text{.10}}{20} ) - 0.609593}{0.609593} = 0.00325 \to 0.325 \% ,$$

which are both significantly lower than 2%.

The strain-thickness product of the AlSb layer and the GaSb/AlSb layer pair is ε_{AlSb}·h_{AlSb}=0.0649 nm, and εₗₚ·hₗₚ=0.065 nm, respectively.

The thickness of the AlSb layer and the total thickness of the GaSb/AlSb layer pair (misfit strain of 0.325%) are also placed lower than the corresponding Matthews critical thicknesses.

FIG. 4 shows an illustration of the strain-thickness characteristics of the AlSb layer and the GaSb/AlSb layer pair of the first GaSb/AlSb superlattice structure.

To build the first SL structure, the AlSb/GaSb layer pair is repeated ten times resulting in a total SL thickness of h_{SL}=hₗₚ·10=200 nm, and strain of ε_{SL}=0.00325→0.325%<2%. The total strain-thickness product of the SL is ε_{SL}·h_{SL}=0.6496 nm, which is significantly lower than the multiplication limit of 0.8 nm.

FIG. 5 is a schematic illustration of the strain-thickness characteristics of the first GaSb/AlSb superlattice comprising ten iterations. As shown in FIG. 5, the strain-thickness characteristic of the SL is placed below the theoretical multiplication line.

(ii) SL2: GaSb 10 nm/AlSb 11 nm, 10 iterations.

Following the same procedure described for SL1, the strain thickness characteristics of the AlSb layer, the GaSb (10 nm)/AlSb (11 nm) layer pair and the second AlSb/GaSb (10 iterations) superlattice are shown in FIG. 6.

(iii) The same procedure is repeated for the third GaSb 11 nm/AlSb 13 nm (9 iterations) and fourth SL: GaSb 14 nm/AlSb 15 nm (8 iterations) superlattice.

The strain-thickness characteristics of these two superlattices are shown in FIG. 7.

FIG. 8 summarizes the strain-thickness characteristic data points obtained for all four GaSb/AlSb dislocation filter superlattices, which satisfy the design rules described above. The squares, the dots and the triangles represent the characteristics obtained for the AlSb layers, the varied AlSb/GaSb layer pairs, and the SLs respectively.

The thickness of the AlSb layers and the GaSb/AlSb layer pair increase when moving towards the top of the structure, while the strain (ε_{AlSb}, ε_{lb}) is kept lower than 2%. The strain-thickness characteristics of the AlSb layers and the GaSb/AlSb layer pairs are placed below the Matthews critical condition line for all four filter structures. As a result, the interfaces should demonstrate an increased defect blocking effect, while avoiding regeneration of threading dislocations due to high strain.

Furthermore, the total strain-thickness product values of the four superlattices increases while moving from the first to the fourth structure. Note that in each case, the strain-thickness characteristics of the SLs were placed below the ε·h=0.8 nm limit line to avoid dislocation multiplication.

### InAs/AlSb Dislocation Filter Superlattice for Growing InAs Buffers

The misfit strain for an AlSb layer grown on InAs is calculated using Equation 2:

$$ε = \frac{{α}_{AlSb} - {α}_{InAs}}{{α}_{InAs}} \text{.100} \% ,$$

where α_{AlSb}=0.61355 nm and α_{InAs}=0.60583 nm, the lattice constants of AlSb and InAs respectively. The strain was calculated as being equal to 1.274%, significantly lower than 2%. Following the Matthews critical thickness rule, the critical thickness of AlSb grown on InAs is approximately 9 nm.

The InAs/AlSb dislocation filter structure design comprises four SLs, each one with varied AlSb, InAs and total SL thickness, as shown in FIG. 9.

Table II summarizes the characteristics of the four superlattices of the InAs/AlSb filter structure.

TABLE II
Strain and thickness characteristics of the InAs/AlSb dislocation filter
superlattice structure consisted of four individual superlattices.

| | | | | | Theoretical |
|---|---|---|---|---|---|
| | SL 1 | SL2 | SL3 | SL4 | Limitations |
| h_{InAs} (nm) | 5 | 5 | 6 | 6 | |
| h_{AlSb} (nm) | 5 | 6 | 7 | 8 | h_{c} ≈ 9 nm |
| ε_{AlSb} (%) | 1.274 | 1.274 | 1.274 | 1.274 | 2% |
| ε_{AlSb} · h_{AlSb} | 0.0637 | 0.0764 | 0.0892 | 0.1019 | |
| (nm) | | | | | |
| hₗₚ (nm) | 10 | 11 | 13 | 14 | |
| εₗₚ (%) | 0.6371 | 0.6951 | 0.6861 | 0.7282 | 2% |
| εₗₚ · hₗₚ (nm) | 0.0637 | 0.0765 | 0.0892 | 0.1019 | |
| Iterations | 10 | 9 | 8 | 7 | |
| h_{SL} (nm) | 100 | 99 | 104 | 98 | |
| ε_{SL} (%) | 0.6371 | 0.6951 | 0.6861 | 0.7282 | 2% |
| ε_{SL} · h_{SL} | 0.6371 | 0.6525 | 0.7135 | 0.7136 | Multiplication |
| (nm) | | | | | limit = 0.8 |

The InAs/AlSb superlattices satisfy the rules described above, as shown in Table II.

FIG. 10 summarizes the strain-thickness characteristics obtained for the four InAs/AlSb superlattices of the structure. The thickness of the AlSb layers and the InAs/AlSb layer pairs increase when moving toward the top of the structure, while the strain of the layer pair is below 2%.

The strain-thickness characteristics of the AlSb layers and of every InAs/AlSb layer pair are placed below the Matthews critical thickness condition line for all four filter structures.

The total strain-thickness product values of the four InAs/AlSb superlattices increases while moving toward the top of the structure. Furthermore, the strain-thickness characteristics of the SLs is placed below and as close as possible to the ε·h=0.8 nm dislocation multiplication limit line.

### GaSb/GaInSb Dislocation Filter Superlattice: Case A

According to this embodiment, the thickness of the GaInSb layer is increased when moving towards the top SL structures, while keeping the composition and strain of the GaInSb layers stable.

The Ga content in the GaInSb layers is 80%. The lattice constant of Ga_{0.8}In_{0.2}Sb was calculated from Vegard's law using the following equation:

α_{Ga}_{ₓ}_{In}_{_{1−x}}_{Sb}=x.α_{GaSb}+(1−x).α_{InSb}, (6)

where x=0.8, 1−x=0.2, α_{GaSb}=0.609593 nm and α_{InSb}=0.6479 nm.

⇒α_{Ga}_{_{0.8}}_{In}_{_{0.2}}_{Sb}=0.8.α_{GaSb}+0.2.α_{InSb}=0.61725 nm.

As such, the misfit strain calculated using Equation 2 is ε_{Ga0.8In0.2Sb}=1.2568%. The Matthews critical thickness for Ga_{0.8}In_{0.2}Sb layers grown on GaSb is approximately 9 nm.

The Ga_{0.8}In_{0.2}Sb dislocation filter structure design comprises varied thickness GaSb and Ga_{0.8}In_{0.2}Sb layers and GaSb/Ga_{0.8}In_{0.2}Sb layer pairs, as shown in FIG. 11. Table III summarizes the characteristics of the GaSb/Ga_{0.8}In_{0.2}Sb superlattices.

TABLE III
Strain and thickness characteristics of the GaSb/Ga_{0.8}In_{0.2}Sb dislocation
filter superlattice structure comprising four individual superlattices.

| | | | | | Theoretical |
|---|---|---|---|---|---|
| | SL 1 | SL2 | SL3 | SL4 | Limitations |
| h_{GaSb} (nm) | 5 | 5 | 6 | 6 | |
| h_{Ga}_{_{0.8}}_{InSb} (nm) | 4 | 5 | 6 | 7 | h_{c} ≈ 9 nm |
| ε_{Ga}_{_{0.8}}_{InSb} (%) | 1.2568 | 1.2568 | 1.2568 | 1.2568 | 2% |
| ε_{Ga}_{_{0.8}}_{InSb} · h_{Ga}_{_{0.8}}_{InSb} (nm) | 0.0502 | 0.0628 | 0.0754 | 0.0880 | |
| hₗₚ (nm) | 9 | 10 | 12 | 13 | |
| εₗₚ (%) | 0.5582 | 0.6280 | 0.6280 | 0.6764 | 2% |
| εₗₚ · hₗₚ (nm) | 0.0502 | 0.0628 | 0.0754 | 0.0880 | |
| Iterations | 13 | 11 | 10 | 9 | |
| h_{SL} (nm) | 117 | 110 | 120 | 117 | |
| ε_{SL} (%) | 0.5582 | 0.6280 | 0.6280 | 0.6764 | 2% |
| ε_{SL} · h_{SL} (nm) | 0.6531 | 0.6908 | 0.7536 | 0.7914 | Multiplication |
| | | | | | limit = 0.8 |

As for the GaSb/AlSb and InAs/AlSb DFSL structure described above, the strain-thickness characteristics of the GaSb/Ga_{0.8}In_{0.2}Sb superlattices satisfy the design rules described above.

The strain-thickness characteristics of the Ga_{0.8}In_{0.2}Sb layers and the GaSb/Ga_{0.8}In_{0.2}Sb layer pairs are placed below the Matthews critical thickness line for all four filter structures, while the strain-thickness characteristics of the GaSb/GaSb/Ga_{0.8}In_{0.2}Sb SLs is placed below the ε·h=0.8 nm dislocation multiplication limit line, as shown in FIG. 12.

### GaSb/GaInSb Dislocation Filter Superlattice: Case B

According to this embodiment, the thickness and/or the strain (composition) of the GaInSb layer is increased when moving towards the top of the filter structure in order to increase the filtering effect.

So far, for all three dislocation filter designs presented above, increase of the strain-thickness product was achieved by using thicker layers. However, for ternary, quaternary, etc. III-V semiconductor alloys, it is possible to increase the strain as well as the strain-thickness product by altering the material composition, not just the thickness of the layer.

As such, an alternative GaSb/GaₓIn₁₋ₓSb DFSL structure was designed comprising GaₓIn₍₁₋ₓ₎Sb layers of varied thickness and composition. Three different compositions were used for the GaₓIn₁₋ₓSb layers, namely Ga_{0.85}In_{0.15}Sb, Ga_{0.82}In_{0.18}Sb and Ga_{0.8}In_{0.2}Sb, as shown in Table III.

The lattice constant and the strain for the three types were calculated using Equations 6 and 3 respectively, with the following results:

α_{Ga0.85In0.15Sb}=0.615339 nm, ε_{Ga0.85In0.15Sb}=0.9426%→h_{c}_{^{Ga0.85In0.15Sb}}≈13 nm

α_{Ga0.82In0.18Sb}=0.616488 nm, ε_{Ga0.82In0.18Sb}=1.1311%→h_{c}_{^{Ga0.82In0.18Sb}}≈10 nm

α_{Ga0.80In0.20Sb}=0.617254 nm, ε_{Ga0.80In0.20Sb}=1.257%→h_{c}_{^{Ga0.80In0.20Sb}}≈9 nm

The critical thickness values were calculated as h_{c}_{^{SL}}≈13 nm, h_{c}_{^{SL2 and SL3}}≈10 nm, and h_{c}_{^{SL4}}≈9 nm for α_{Ga0.85In0.15Sb}, α_{Ga0.82In0.18Sb} and α_{Ga0.80In0.20Sb} respectively using the Matthews rule.

As shown in FIG. 13, the dislocation filter structure comprises four GaSb/GaₓIn₍₁₋ₓ₎Sb SLs and varied thicknesses as well as composition (GaSb, Ga_{0.85}In_{0.15}Sb, Ga_{0.82}In_{0.18}Sb and Ga_{0.8}In_{0.2}Sb) GaInSb layers. Table IV summarizes the strain thickness characteristics of the structure.

The strain-thickness characteristics of the varied GaₓIn₍₁₋ₓ₎Sb layers and the GaSb/GaₓIn₍₁₋ₓ₎Sb layer pairs are placed below the Matthews line for all four filter structures, while the strain-thickness characteristics of the GaSb/GaₓIn₍₁₋ₓ₎Sb SLs are placed below the ε·h=0.8 nm dislocation multiplication line, as shown in FIG. 14.

TABLE IV
Composition, strain and thickness characteristics of the GaSb/GaₓIn₍₁₋ₓ₎Sb dislocation
filter superlattice structure comprising four individual superlattices.

| | | | | | Theoretical |
|---|---|---|---|---|---|
| | SL 1 | SL2 | SL3 | SL4 | Limitations |
| h_{GaSb} (nm) | 5 | 6 | 6 | 7 | |
| Composition of | Ga: 85%/ | Ga: 8.2%/ | Ga: 82%/ | Ga: 80%/ | |
| GaInSb | In: 15% | In: 18% | In: 18% | In: 20% | |
| h_{GaInSb} (nm) | 6 | 6 | 7 | 7 | h_{c}_{_{SL1}} ≈ 13 nm, h_{c}_{_{SL2 and SL3}} ≈ |
| | | | | | 10 nm and h_{c}_{_{SL4}} ≈ 9 nm |
| ε_{GaInSb} (%) | 0.9426 | 1.1311 | 1.1311 | 1.2568 | 2% |
| ε_{GaInSb} · h_{GaInSb} | 0.0566 | 0.0679 | 0.0792 | 0.0880 | |
| (nm) | | | | | |
| hₗₚ (nm) | 11 | 12 | 13 | 14 | |
| εₗₚ (%) | 0.5141 | 0.5656 | 0.6091 | 0.6284 | 2% |
| εₗₚ · hₗₚ (nm) | 0.0566 | 0.0679 | 0.0792 | 0.0880 | |
| Iterations | 11 | 10 | 9 | 9 | |
| h_{SL} (nm) | 121 | 120 | 117 | 126 | |
| ε_{SL} (%) | 0.5141 | 0.5656 | 0.6091 | 0.6284 | 2% |
| ε_{SL} · h_{SL} (nm) | 0.6221 | 0.6787 | 0.7126 | 0.7918 | Multiplication limit = 0.8 |

The dislocation filter structures described above can be used as an advanced buffer layer to enable the direct integration of a variety of semiconductor electrical devices, such as light emitting diodes, diode lasers, vertical cavity surface emitting lasers (VCSELs), detector arrays, transistors and memories, on large and low cost wafers such as GaAs and Si.

In the case of Si, this opens up the possibility for integration of compound semiconductors for Si photonic applications. Depending on the active region of the device, the operation wavelength could potentially be tuned across a wide range of the electromagnetic spectrum. For GaSb materials, this includes the 1.3-15 μm range, which also covers the mid-infrared spectral region from 2-5 μm.

A GaSb/AlSb DFSL structure has been grown based on the design rules described above, resulting in a surface dislocation density of the order of 10⁶ cm⁻². This value is the lowest reported so far for Sb-based materials integrated on Si.

A variety of other material combinations could be used to design effective dislocation filter structures with increasing strain and/or strain-thickness product, such as InAsSb/InAs, GaInAsSb/GaSb, GaAsSb/GaAs, GaAsP/GaAs, InP/InAsP, etc.

For ternary, or higher order alloys, the strain and/or the strain-thickness product can be increased by changing the layer composition alongside increasing the layer thicknesses when moving towards the top of the structures. However, as the alloy composition is very sensitive to temperature and growth rate variations, it is believed that control of the inserted strain in such filters will be more difficult as compared to a filter structure comprising only binary III-V semiconductor layers.

Depending on the material system and the starting defect density, a number of dislocation filters structures can be used to create an effective filter structure. However, it should be noted that the use of a very high number of superlattice repetitions is not practical since the net strain will be too high in the structure, resulting in defect or crack generation. Furthermore, the resultant buffer layers will be too thick and expensive to manufacture.

Furthermore, the spacer layers placed between the filters may have a variety of thicknesses, depending on the type and net strain of the underlying filter structure.

A high order of defect densities are observed in a variety of lattice mismatched systems, such as GaAs/Si, GaAs/Ge, GaP/Si, InAs/Si, GaN/Si etc. The dislocation filter design rules presented herein can be used to create a compatible dislocation filter structures for all of these lattice mismatched systems in order to reduce the number of threading dislocations reaching the surface of the epitaxial layers.

Tensile stain present at interfaces such as GaN/Si and GaP/Si require careful attention as high strain can lead to the generation of cracks which can interfere with the dislocation filtering mechanism. It is also important to note that in such systems, reaction of threading dislocations lead to the formation of immobile dislocations which makes the design of effective dislocation filters structures more difficult.

Furthermore, in general, integration of III-V semiconductors is possible using a variety of growth techniques such as molecular beam epitaxy (MBE) and metalorganic vapor-phase epitaxy (MOCVD). MBE is considered as being one of the best options to grow high crystalline quality dislocation filters as it enables precise and accurate control of the composition and thickness of the layers of the superlattices. On the other hand, MOCVD is preferred for high volume applications.

It will be appreciated that various embodiments provide a semiconductor device comprising a semiconductor substrate and one or more mismatched epitaxial layers. A series of strained superlattice dislocation filter layers are used to remove the threading dislocations arising from the lattice mismatch between the substrate and epitaxial layers.

The superlattice dislocation filter layers are designed so that the strain-thickness product of each SL is lower than 0.8 nm. The strain-thickness product of the pair of layers increases towards the top of the SL structure. The thickness and/or the strain of the layers increases when moving towards the top of the structure. Increasing the strain of the layers can be achieved by changing the material composition. The strain-thickness product of the superlattice filter structure can be controlled through the choice of a binary, ternary or higher order compound semiconductor alloy.

1. A semiconductor structure comprising:
a substrate;
one or more first semiconductor layers; and
a plurality of superlattice structures between the substrate and the one or more first layers, wherein the plurality of superlattice structures comprises an initial superlattice structure and one or more further superlattice structures between the initial superlattice structure and the one or more first layers;
wherein the plurality of superlattice structures is configured such that a strain-thickness product of semiconductor layer pairs in each superlattice structure of the one or more further superlattice structures is greater than or equal to a strain-thickness product of semiconductor layer pairs in superlattice structure(s) of the plurality of superlattice structures between that superlattice structure and the substrate; and
wherein the plurality of superlattice structures is configured such that a strain-thickness product of semiconductor layer pairs in at least one of the one or more further superlattice structures is greater than a strain-thickness product of semiconductor layer pairs in the initial superlattice structure.

2. The semiconductor structure of claim 1, wherein the plurality of superlattice structures is configured such that a strain-thickness product of semiconductor layer pairs in each superlattice structure of the one or more further superlattice structures is greater than a strain-thickness product of semiconductor layer pairs in superlattice structure(s) of the plurality of superlattice structures between that superlattice structure and the substrate.

3. The semiconductor structure of claim 1, wherein the plurality of superlattice structures is configured such that the strain-thickness product of each semiconductor layer and/or layer pair in each superlattice structure of the plurality of superlattice structures is less than a limit as defined by Equation 1:
$$\underline{ϵ = \frac{b}{2 {h}_{c} cos ( λ )} ( \frac{1}{10} + \frac{1}{4 π} \frac{1 - v {cos}^{2} ϑ}{1 - v} ln ( \frac{{h}_{c}}{b} ) )} .$$

4. The semiconductor structure of claim 1, wherein:
the plurality of superlattice structures is configured such that the thickness of semiconductor layer pairs in each superlattice structure of the one or more further superlattice structures is greater than or equal to the thickness of semiconductor layer pairs in superlattice structure(s) of the plurality of superlattice structures between that superlattice structure and the substrate; and
the plurality of superlattice structures is configured such that the thickness of semiconductor layer pairs in at least one of the one or more further superlattice structures is greater than the thickness of semiconductor layer pairs in the initial superlattice structure.

5. The semiconductor structure of claim 1, wherein:
the plurality of superlattice structures is configured such that the strain of semiconductor layer pairs in each superlattice structure of the one or more further superlattice structures is greater than or equal to the strain of semiconductor layer pairs in superlattice structure(s) of the plurality of superlattice structures between that superlattice structure and the substrate; and
the plurality of superlattice structures is configured such that the strain of semiconductor layer pairs in at least one of the one or more further superlattice structures is greater than the strain of semiconductor layer pairs in the initial superlattice structure.

6. The semiconductor structure of claim 5, wherein:
each semiconductor layer pair comprises a first semiconductor layer and a second semiconductor layer; and
the plurality of superlattice structures is configured such that the semiconductor material and/or the composition of the semiconductor material of each first layer of one or more superlattice structure(s) of the plurality of superlattice structures is different to the semiconductor material and/or the composition of the semiconductor material of each first layer of one or more other superlattice structure(s) of the plurality of superlattice structures; and/or
the plurality of superlattice structures is configured such that the semiconductor material and/or the composition of the semiconductor material of each second layer of one or more superlattice structure(s) of the plurality of superlattice structures is different to the semiconductor material and/or the composition of the semiconductor material of each second layer of one or more other superlattice structure(s) of the plurality of superlattice structures.

7. The semiconductor structure of claim 1, wherein the plurality of superlattice structures is configured such that a strain-thickness product of each superlattice structure of the plurality of superlattice structures is less than about 0.8 nm.

8. The semiconductor structure of claim 1, wherein:
the plurality of superlattice structures is configured such that a strain-thickness product of each superlattice structure of the one or more further superlattice structures is greater than or equal to a strain-thickness product of superlattice structure(s) of the plurality of superlattice structures between that superlattice structure and the substrate; and
the plurality of superlattice structures is configured such that a strain-thickness product of at least one of the one or more further superlattice structures is greater than a strain-thickness product of the initial superlattice structure.

9. The semiconductor device of claim 1, wherein:
the plurality of superlattice structures is configured such that the number of repeats in each superlattice structure of the one or more further superlattice structures is less than or equal to the number of repeats in superlattice structure(s) of the plurality of superlattice structures between that superlattice structure and the substrate; and
the plurality of superlattice structures is configured such that the number of repeats in at least one of the one or more further superlattice structures is less than the number of repeats in the initial superlattice structure.

10. The semiconductor device of claim 1, wherein the lattice constant of the semiconductor material of the one or more first layers is different to the lattice constant of the semiconductor material of the substrate.

11. The semiconductor device of claim 1, wherein the substrate is formed from silicon (Si), Germanium (Ge) or Gallium Arsenide (GaAs).

12. The semiconductor device of claim 1, wherein the one or more first layers are formed from one or more III-V compound semiconductor materials such as Gallium Antimonide (GaSb), Gallium Arsenide (GaAs), Gallium Phosphide (GaP), Gallium Nitride (GaN), Gallium Arsenide Antimonide (GaAsSb), Gallium Indium Antimonide (GaInSb), Gallium Arsenide Phosphide (GaAsP), Gallium Indium Arsenide Antimonide (GaInAsSb), Indium Arsenide (InAs), Indium Phosphide (InP), Indium Arsenide Antimonide (InAsSb), Aluminium Antimonide (AlSb), or Aluminium Indium Antimonide (AlInSb).

13. A semiconductor device comprising the semiconductor structure of claim 1.

14. The semiconductor device of claim 13, wherein the semiconductor device comprises a light-emitting device, a detecting device, and/or an electronic device.

15. A method of forming a semiconductor structure, the method comprising:
forming an initial set of semiconductor layers on a substrate; and
forming one or more first semiconductor layers on the initial set of semiconductor layers;
wherein forming the initial set of semiconductor layers comprises forming a plurality of superlattice structures comprising an initial superlattice structure and one or more further superlattice structures;
wherein forming the plurality of superlattice structures comprises forming the plurality of superlattice structures such that a strain-thickness product of semiconductor layer pairs in each superlattice structure of the one or more further superlattice structures is greater than or equal to a strain-thickness product of semiconductor layer pairs in superlattice structure(s) between that superlattice structure and the substrate; and
wherein forming the plurality of superlattice structures comprises forming the plurality of superlattice structures such that a strain-thickness product of semiconductor layer pairs in at least one of the one or more further superlattice structures is greater than a strain-thickness product of semiconductor layer pairs in the initial superlattice structure.
